(19) United States
(12) Patent Application Publication
(10) Pub. No.: US 2015/0272263 A1
(43) Pub. Date: Oct. 1, 2015

(54) Energy-Saving Wearable Piezoelectric Transportation Device

(71) Applicant: Balint Szent-Miklosy, New York City, NY (US)

(72) Inventor: Balint Szent-Miklosy, New York City, NY (US)

(73) Assignee: Futurific, Inc., New York City, NY (US)

(21) Appl. No.: 14/739,395

(22) Filed: Jun. 15, 2015

(51) Int. Cl. A43B 3/00; A43B 13/14; H01L 41/08

(52) U.S. Cl. CPC A43B 3/0015; H01L 41/0825; A43B 13/14

(57) ABSTRACT

Disclosed is a piezoelectric wearable device that simultaneously harvests and utilizes energy. In one embodiment, the present invention includes footwear having piezoelectric elements and a plurality of plungers on the outer sole thereof. In operation, the plungers act in alternate sequences such that a first set of rows retracts or rises off of the ground while a second set of rows extends or drops towards the ground. The piezoelectric elements include piezoelectric transducers, each having a sensor and a piezoelectric ceramic embedded therein. When activated, the sensor captures the electrical charge produced therefrom. Thereafter, the piezoelectric ceramic can convert the electric charge into energy, which is then stored and used to propel the footwear in any direction, wherein the wearer may control the direction via an external electronic device.

### FIELD OF THE INVENTION

The present invention generally relates to an energy-saving wearable transportation device. More particularly, the present invention is directed to a wearable device that utilizes piezoelectricity in order to facilitate moving.

### BACKGROUND OF THE INVENTION

The piezoelectric effect is understood as the linear electromechanical interaction between the mechanical and the electrical state in crystalline materials with no inversion symmetry. The piezoelectric effect is a reversible process in that materials exhibiting the direct piezoelectric effect (the internal generation of electrical charge resulting from an applied mechanical force) also exhibit the reverse piezoelectric effect (the internal generation of a mechanical strain resulting from an applied electrical field). When piezoelectric material is placed under mechanical stress, a shifting of the positive and negative charge in the material center takes place, which then results in an external electrical field. When reversed, an outer electrical field either stretches or compresses the piezoelectric material.

There are many applications for the inverse piezoelectric effect. For example, the inverse piezoelectric effect is used in production of ultrasonic sound waves. Applications for harvesting energy and generating electricity using the piezoelectric effect have become more of a focus in recent times, however. More specifically, harvesting energy and generating electricity from human movements is currently being expanded. Recently, piezoelectric floors have been trialed in public places such as train stations and recreation areas. The electricity generated from the foot traffic is used to provide all the electricity needed to run electronics such as the automatic ticket gates and electronic display systems. However, the piezoelectric tile deployed on the ground usually harvests energy from low frequency strikes provided by the foot traffic. This working condition may eventually lead to lower power generation efficiency.

In this regard, locating high traffic areas is critical for optimization of the energy harvesting efficiency, as well as the orientation of the tile pavement significantly affects the total amount of the harvested energy. Thus, existing piezoelectric floors can be inefficient and underutilized. Additionally, constructing piezoelectric floors and roads is a resource-intensive job that is expected to use a vast amount of resources. Thus, there is a need for a cost effective and useful device that can ease transporting individuals while harvesting energy.

### SUMMARY OF THE INVENTION

In view of the disadvantages inherent in the known types of devices for harvesting energy utilizing piezoelectric technology now present in the prior art, the present invention provides an improved wearable device that utilizes piezoelectricity wherein the same can be used for harvesting energy while facilitating moving and transporting individuals.

The present invention is advantageous in that it is substantially self-powered device that can be also used by the elderly or other individuals with limited mobility. In one embodiment, the present invention comprises footwear having a plurality of piezoelectric elements on the outer sole thereof. In another embodiment, the present invention comprises footwear having a removably attached outer sole thereon, wherein the outer sole comprises a plurality of piezoelectric elements. Each of the piezoelectric elements comprises a piezoelectric transducer having a sensor and a piezoelectric ceramic embedded therein. Additionally, each of the piezoelectric elements is connected to a plurality of plungers disposed on the bottom surface of the outer sole of the footwear, wherein the plungers are configured to move.

When the footwear is activated via a control unit, the plungers contact the ground and the sensor captures the electrical charge produced thereby. Thereafter, the piezoelectric ceramic can convert the electric charge into energy, which is then stored and used to move the plungers and propel the wearer in any direction of choosing. The control unit or another suitable portable electronic device can be used to control the direction of travel, wherein the electronic device comprises a mobile computing device, a mobile phone, or a tablet computer having a software application thereon, and further wherein the application is programmed to communicate with the footwear and transmit commands. Accordingly, some embodiments of the present invention further comprise a communication module embedded within the footwear.

The plungers act in alternate sequences such that a first set of rows of the plungers retracts or rises off of the ground while a second set of rows of the plungers extends or drops towards the ground. It is contemplated that each set comprises approximately one half of the plungers disposed on the outer sole of the footwear. Additionally, the plungers may be disposed at an angle relative to the outer sole, so that they create horizontal displacement as they push off of the ground in operation. In this way, the piezoelectric elements create propulsion, allowing the wearer to move in a convenient manner without moving his or her feet. The present invention may be used for walking when not activated, however.

It is therefore an object of the present invention to provide footwear that can distribute weight and propel the body of the wearer in any direction while generating electricity for immediate reuse thereof.

It is another object of the present invention to provide footwear that comprises removably attached outer soles having piezoelectric elements thereon.

It is still another object of the present invention to provide footwear that comprises piezoelectric elements integral to the outer sole thereof.

It is still another object of the present invention to provide a wearable device that utilizes piezoelectric technology to simultaneously harvest and use energy.

A final object of the present invention to provide footwear that may be readily fabricated from materials that permit relative economy and commensurate with durability.

In the light of the foregoing, these and other objects are accomplished in accordance of the principles of the present invention, wherein the novelty of the present invention will become apparent from the following detailed description and appended claims.

### BRIEF DESCRIPTION OF THE DRAWINGS

The above and other objects and advantages of the present invention will be apparent upon consideration of the following detailed description, taken in conjunction with the accompanying exemplary drawings, in which like reference characters refer to like parts throughout, and in which:

FIG. 1 is a perspective view of an exemplary embodiment of the present invention.

FIG. 2 is a bottom perspective view of the exemplary embodiment of the present invention.

FIG. 3A shows a side planar view of a second embodiment of the present invention.

FIG. 3B shows a bottom view of the outer sole of the second embodiment of the present invention.

FIG. 4 shows an exemplary circuit diagram of the present invention.

### DETAILED DESCRIPTION OF THE INVENTION

The present invention is directed towards a wearable device that utilizes piezoelectricity to facilitate moving. For purposes of clarity, and not by way of limitation, illustrative views of the present footwear that utilizes piezoelectricity are described with references made to the above-identified figures. Various modifications obvious to one skilled in the art are deemed to be within the spirit and scope of the present invention.

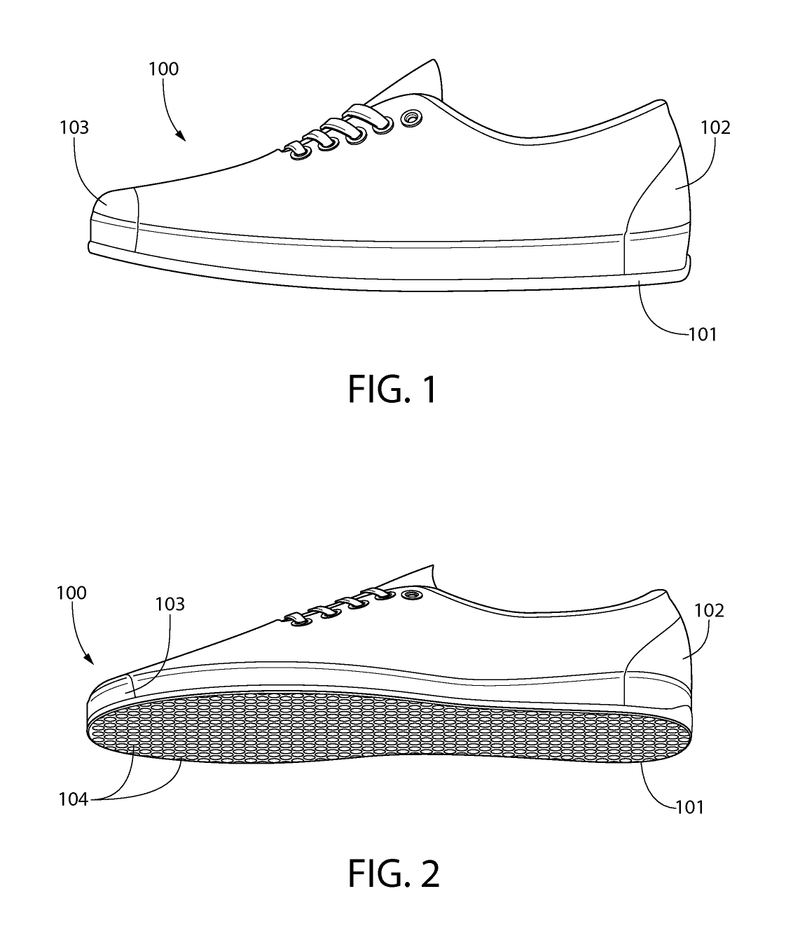

Referring now to FIGS. 1 and 2, there is shown a perspective view and a bottom perspective view of an exemplary embodiment of the present invention, respectively. In the illustrated embodiment, the present invention comprises footwear 100, wherein the footwear 100 resembles a conventional shoe. Without limitation, the present invention could also take the form of any other kind of footwear, including, athletic shoes, dress shoes, boots, slippers, or the like. Accordingly, the footwear 100 comprises a forefoot portion 103, a midfoot portion, and a rearfoot portion 102, wherein the rearfoot portion 102 comprises an opening along the top thereof that provides access to the interior cavity of the footwear 100.

The opening is configured for receiving a wearer's foot therethrough. In some embodiments, the interior cavity of the footwear 100 comprises a cushioned insole that is adapted to directly contact the wearer's foot. The cushioned insole is shaped and dimensioned to snugly fit along the lower surface of the interior cavity of the footwear 100. The footwear 100 further comprises an outer sole 101 on the bottom surface thereof, wherein the outer sole 101 spans from the forefoot portion 103 to the rearfoot portion 102. The outer sole 101 is configured to contact a ground surface and therefore composed of a durable material that can protect the wearer's feet from outside elements.

The outer sole 101 comprises a top surface that is coextensive with a bottom surface thereof, wherein the top surface is attached to the bottom surface of the footwear 100. It is contemplated that the outer sole 101 is attached via adhesives or the like. The bottom surface of the outer sole 101 comprises a plurality of plungers 104 thereon. The outer sole 101 and the plungers 104 comprise a high friction exterior surface so as to provide traction and to prevent skidding when moving, thereby providing maximum contact between the outer sole 101 and the surface on which the wearer is moving. Preferably, the plungers 104 are connected to the bottom surface of the outer sole 101 in a parallel configuration so as to create rows and/or columns. In some embodiments, the plungers 104 may be covered with a layer of outer sole material so that it is embedded within the outer sole 101 and not visible from the exterior thereof.

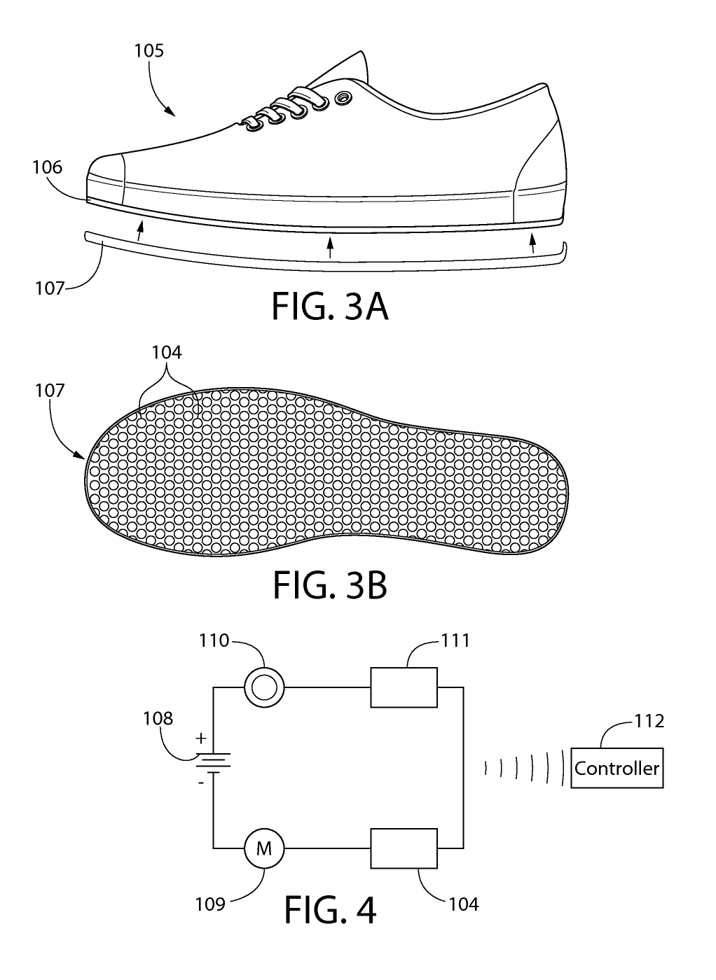

Referring now to FIGS. 3A and 3B, there are shown views of a second embodiment of the present invention. The second embodiment of the present invention comprises footwear 105 and a piezoelectric outer sole 107, wherein the piezoelectric outer sole 107 is configured to removably attach to the existing outer sole 106 of the footwear 105. The piezoelectric outer sole 107 comprises a top surface that is coextensive with a bottom surface. Preferably, the piezoelectric outer sole 107 can removably attach to the existing outer sole 106 of the footwear 105 via press-fit or snap-fit. Accordingly, the top surface of the piezoelectric outer sole 107 comprises a groove or an indentation along the perimeter thereof for receiving the outer sole 106 of the footwear 105. It is contemplated, however, that the piezoelectric outer sole 107 can attach via other fastening means such as straps, clips, snap buttons, and the like.

Similar to the first embodiment, the bottom surface of the piezoelectric outer sole 107 comprises a plurality of plungers 104 connected thereto such that the plungers 104 are substantially at an angle relative to the bottom surface. Further, the plungers 104 are preferably arranged in a parallel configuration so as to create rows or columns, and are spaced apart at regular intervals. In the illustrated embodiment, the plungers 104 comprise a substantially cylindrical housing member with a defined interior volume for storing necessary internal circuitry to connect to the piezoelectric elements.

In either embodiments, the plungers 104 can rise or retract towards the bottom surface of the footwear 100, 105. Conversely, the plungers 104 can also drop or extend downward toward the ground surface and away from the bottom surface of the footwear 100, 105 via gravity. Thus, in operation, the plungers 104 can act in alternate sequences such that one set of rows or approximately one half of the plungers 104 retract while another set of rows or the other half of the plungers 104 extend downward.

In one embodiment, the two sets of plungers 104 are configured to move in a synchronized manner so that every other row of plungers 104 retracts while the adjacent rows of plungers 104 extend. Because the plungers 104 are disposed at an angle relative to the bottom surface of the footwear 100, 105, the plungers 104 can propel the footwear 100, 105 forward, backward, or sideways as they push against the ground when retracting. In this regard, the footwear 100, 105 can move without requiring the wearer to actuate the footwear 100, 105. Additionally, the footwear 100, 105 can move smoothly in unison.

The pressure from the wearer's weight generates electricity, which is harvested and immediately used by the plungers 104 to retract when activated. The pressure also causes the plungers 104 to buckle, moving the wearer in the direction of travel. In a preferred embodiment, the piezoelectric elements harvest sufficient amount of energy that can be immediately reused. In some embodiments, however, the present invention may comprise a supplemental power supply such as rechargeable batteries that can be integral to the footwear 100, 105 or worn on the wearer's person. For example, the battery can be built into the wearer's clothing, removably attached to the wearer's clothing, or removably attached to the wearer's belt loop or backpack.

Referring now to FIG. 4, there is shown an exemplary circuit diagram of the present invention. The outer sole of the footwear comprises piezoelectric elements 110, each of the piezoelectric elements 110 having a piezoelectric transducer. The piezoelectric transducer comprises a housing member comprising a defined interior volume therein. The interior of the housing member is insulated and comprises a sensor and an alternating current that is connected to a pair of electrodes having a piezoelectric ceramic therebetween. The sensor is configured to detect weight, pressure, motion, vibration, and/or temperature changes, depending upon embodiment.

The electrodes provide attachment points for electrical contact. In an exemplary embodiment, the present invention comprises a single sheet of piezoelectric ceramic sandwiched between a pair of electrodes. In other embodiments, however, the present invention comprises a plurality of piezoelectric ceramic sheets. In such embodiments, the piezoelectric ceramic and the electrodes are stacked so that the ceramic and the electrodes alternate.

Without limitation, the piezoelectric ceramic comprises polycrystalline ferroelectric ceramics such as barium titanate, lead metaniobate, lead zirconate titanate (PZT), polyvinylidene difluoride film, or other suitable materials. The piezoelectric ceramic, when mechanically activated with weight, motion, pressure, vibration, and/or temperature changes, has the capacity to generate electric current or voltages.

The piezoelectric elements 110 are connected to the plungers 104, which is activated via a controller 112 and connected thereto via a wireless communication module 111. Once the plungers 104 are activated via the controller 112, a positive charge is produced from the piezoelectric elements 110. Thereafter, when the weight or the pressure is relieved or the vibration or the temperature changes stop, electrical current flows across the piezoelectric ceramic. The electrical charge produced by the weight, motion, pressure, vibration, and/or temperature change is captured by the sensor, converted to an electrical charge by the piezoelectric ceramic, then stored and used as a power source.

Thus, the piezoelectric ceramic harvests some of the energy, which the wearer loses to the environment while moving. It is contemplated that the heavier the wearer, the greater the amount of energy in return, as the heavier wearer would apply more weight, motion, pressure, vibration, and/or temperature change when moving. The electrical energy produced by a multilayer piezoelectric transducer is of a much lower voltage than is generated by a single-layer piezoelectric transducer. On the other hand, the current produced by a multilayer piezoelectric transducer is significantly higher than the current generated by a single-layer piezoelectric transducer. The piezoelectric transducer utilizes the piezoelectric property of the piezoelectric ceramic to convert electrical energy (AC) directly into mechanical energy (DC).

In some embodiments, the present invention further comprises a motor 109 for assisting in driving the plungers upwards and off of the ground. The motor 109 applies directional force to the bottom of the footwear, causing it, and the footwear to move in the desired direction. More specifically, the motor is adapted to propel the footwear in a direction of choosing by actuating one set of the plungers 104, or approximately one half of the plungers 104, to extend from the outer sole of the footwear. After the plungers 104 retract, they can automatically descend back downward via gravity.

Although it is contemplated that some embodiments of the present invention is configured to harvest sufficient amount of energy to be utilized for facilitating the wearer when moving, other embodiments of the present invention may comprise a supplemental power source. In the illustrated embodiment, the piezoelectric element 110 is connected to a power supply 108 such as rechargeable batteries. The rechargeable batteries 108 can be embedded within the footwear of the present invention such that it is integral thereto. The rechargeable batteries can also be an external unit that can be carried on the wearer's person. Alternatively, the present invention may comprise a port for connecting to a charging cable that connects to an electrical outlet.

It is therefore submitted that the instant invention has been shown and described in what is considered to be the most practical and preferred embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

1. A wearable energy harvesting device, comprising:
a footwear having a piezoelectric outer sole on a bottom surface thereof;
said piezoelectric outer sole having piezoelectric elements and a plurality of plungers thereon;
each of said piezoelectric elements having a piezoelectric transducer;
wherein said plurality of plungers extends away from said piezoelectric outer sole when activated via a controller, generating electricity and applying directional force to cause horizontal displacement;
further wherein said plurality of plungers retracts towards said piezoelectric outer sole, utilizing said electricity;
a power source connected to said piezoelectric elements.

2. The wearable energy harvesting device of claim 1, wherein a first set and a second set of said plurality of plungers move in alternate sequences such that said first set of plungers retracts while said second set of plungers extends.

3. The wearable energy harvesting device of claim 1, wherein said piezoelectric outer sole is removably attached to said bottom surface of said shoe.

4. The wearable energy harvesting device of claim 1, wherein said plurality of piezoelectric elements is arranged in a parallel configuration.

5. The wearable energy harvesting device of claim 1, wherein said power source comprises rechargeable batteries.

6. The wearable energy harvesting device of claim 1, wherein said rechargeable batteries is structurally separate from said footwear.

7. The wearable energy harvesting device of claim 1, wherein said power source is integral to said piezoelectric outer sole.

8. The wearable energy harvesting device of claim 1, wherein said plurality of plungers is disposed at an angle relative to said bottom surface.
